(19) United States
(12) Patent Application Publication
(10) Pub. No.: US 2010/0161883 A1
(43) Pub. Date: Jun. 24, 2010

(54) Nonvolatile Semiconductor Memory Drive and Data Management Method of Nonvolatile Semiconductor Memory Drive

(75) Inventor: Takehiko Kurashige, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Kabushiki Kaisha Toshiba, Tokyo (JP)

(21) Appl. No.: 12/546,510

(22) Filed: Aug. 24, 2009

(30) Foreign Application Priority Data
Dec. 24, 2008 (JP) 2008-328713

(51) Int. Cl. G06F 12/00; G06F 12/02; H03M 13/05; G06F 11/10

(52) U.S. Cl. 711/103; 711/154; 711/E12.001; 714/768; 714/E11.032; 711/E12.008

(57) ABSTRACT

According to one embodiment, a nonvolatile semiconductor memory drive includes a nonvolatile semiconductor memory, and a controller which controls a process of writing and reading data with respect to the nonvolatile semiconductor memory. The controller includes a logical address storage module which stores logical address information containing logical addresses indicating storage positions in a logical address space of the nonvolatile semiconductor memory in a redundant area of a page, and a data management module which creates parity data used to restore one logical address information items among n-1 logical address information items stored in redundant areas of n-1 pages based on the other n-2 logical address information items and writes the created second parity data to the redundant area of the n^{th} page.

### CROSS-REFERENCE TO RELATED APPLICATIONS

This application is based upon and claims the benefit of priority from Japanese Patent Application No. 2008-328713, filed Dec. 24, 2008, the entire contents of which are incorporated herein by reference.

### BACKGROUND

1. Field

One embodiment of the invention relates to a data management technique for enhancing data redundancy in a nonvolatile semiconductor memory drive such as a solid-state drive (SSD), for example.

2. Description of the Related Art

Recently, portable, battery-driven notebook personal computers called mobile PCs have become popular. In most personal computers of this type, a wireless communication function is provided or a wireless communication function can be added as required by connecting a wireless communication module to a universal serial bus (USB) connector or inserting such a module into a PC card slot. Therefore, if the user carries the mobile PC with him, he can create and send documents or acquire various kinds of information at any location or while on the move.

Further, since it is required that a personal computer of this type be portable, highly shock-resistant and usable for long periods when powered by battery, research into ways to make devices smaller and lighter, enhance shock-resistance and reduce power consumption is in progress. Against this background, mobile notebook PCs incorporating flash-memory-based SSDs instead of hard disk drives (HDDs) have recently begun to be manufactured and sold.

For a device using a flash memory, various mechanisms for efficiently managing data have been proposed (for example, see Jpn. Pat. Appln. KOKAI Publication No. 2008-204041).

As a storage area management method for maintaining the data write efficiency, compaction is well known. When it is assumed that a plurality of groups are constructed as a storage area management unit, compaction is a process of selecting, for example, two groups in which the capacity of invalid data (that occurs when data is updated at the additional write time) is increased, putting valid data of the two groups into one group and resetting one group to an unused state. The data write efficiency can be maintained by appropriately performing the compaction process to securely acquire a free group in the unused state.

In an external storage device containing the SSD, a data write or read request is received together with a logical address indicating a position in a logical address space, the logical address is converted into a physical address indicating a position in a physical address space, and data is written at the position indicated by the physical address or data stored in the position indicated by the physical address is read. For conversion from the logical address to the physical address, the external storage device manages an address table (cluster table). Therefore, when data rearrangement such as the compaction is performed, it is necessary to update the address table.

When updating the address table accompanied by the data rearrangement, it is necessary to acquire a logical address from the physical address indicating the storage position before rearrangement of to-be-rearranged data. As one method of efficiently acquiring the logical address, for example, it is considered to provide a redundant area of a page that stores data and previously store a logical address set in correspondence to the physical address indicating the storage position of the data in the redundant area. In this case, a mechanism for restoring information stored in the redundant area of each page when a read error occurs in the page is required.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary view showing an external appearance of an information processing apparatus (computer) according to one embodiment of the invention;

FIG. 2 is an exemplary diagram showing a system configuration of the computer of the embodiment;

FIG. 3 is an exemplary block diagram showing the schematic configuration of an SSD installed as a boot drive in the computer of the embodiment;

FIG. 4 is an exemplary conceptual diagram showing the schematic configuration of a NAND memory incorporated in the SSD installed in the computer of the embodiment;

FIG. 5 is an exemplary conceptual diagram for illustrating the operation principle of the SSD installed in the computer of the embodiment;

FIG. 6 is an exemplary conceptual diagram for illustrating the parity data creation and write principle realized by an SSD installed in the computer of the embodiment;

FIG. 7 is an exemplary conceptual diagram for illustrating a management of a correspondence relationship between a physical address space and a logical address space of the NAND memories performed by an SSD installed in the computer of the embodiment;

FIG. 8 is an exemplary flowchart for illustrating the operation procedure of a data write process performed by an SSD installed in the computer of the embodiment;

FIG. 9 is an exemplary flowchart for illustrating the operation procedure of a data read process performed by an SSD installed in the computer of the embodiment; and

FIG. 10 is an exemplary flowchart for illustrating the operation procedure of a patrol process performed by an SSD installed in the computer of the embodiment.

### DETAILED DESCRIPTION

Various embodiments according to the invention will be described hereinafter with reference to the accompanying drawings. In general, according to one embodiment of the invention, a nonvolatile semiconductor memory drive includes a nonvolatile semiconductor memory, and a controller which controls a process of writing and reading data with respect to the nonvolatile semiconductor memory. The controller includes a logical address storage module which stores logical address information containing logical addresses indicating storage positions in a logical address space of the nonvolatile semiconductor memory in a redundant area of a page, and a data management module which creates parity data used to restore one logical address information items among n-1 logical address information items stored in redundant areas of n-1 pages based on the other n-2 logical address information items and writes the created second parity data to the redundant area of the n^{th} page.

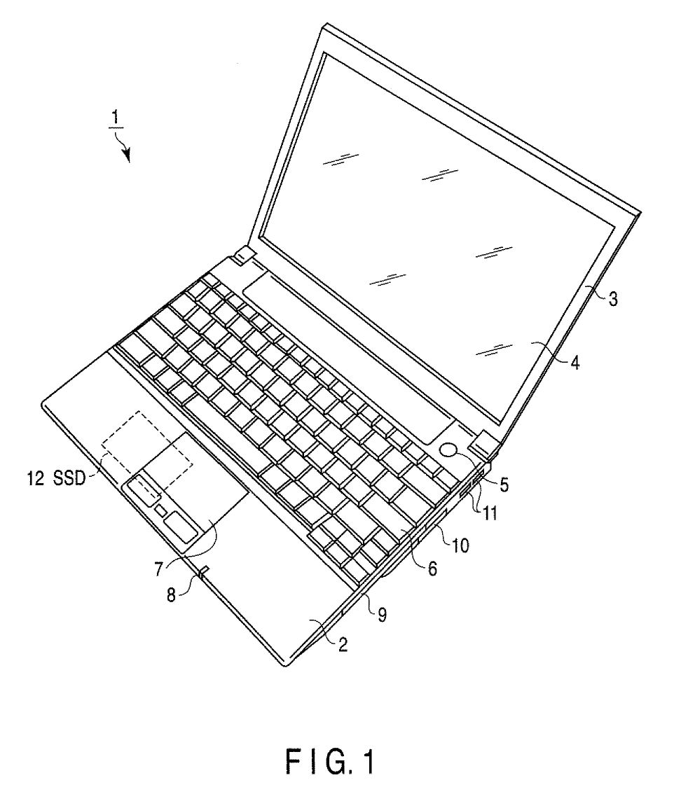

FIG. 1 is an exemplary view showing the external appearance of an information processing apparatus according to this embodiment. For example, the information processing apparatus is realized as a notebook personal computer 1 that can be battery-driven and is called a mobile note PC.

The computer 1 includes a computer main body 2 and display unit 3. In the display unit 3, a display device configured by a liquid crystal display (LCD) 4 is incorporated.

The display unit 3 is rotatably installed in the computer main body 2 so as to be freely rotated between an open position in which the upper surface of the computer main body 2 is exposed and a closed position in which the upper surface of the computer main body 2 is covered with the display unit 3. The computer main body 2 is formed of a thin box-form casing and a power source switch 5, keyboard 6, touchpad 7 and the like are arranged on the upper surface thereof.

Further, a light-emitting diode (LED) 8 is arranged on the front surface of the computer main body 2 and an optical disc drive (ODD) 9 that can write and read data with respect to a Digital Versatile Disc (DVD) or the like, a PC card slot 10 that removably accommodates a PC card, a USB connector 11 used for connection with a USB device and the like are arranged on the right-side surface thereof. The computer 1 includes an SSD 12 that is a nonvolatile semiconductor memory drive provided in the computer main body 2 as an external storage device used as a boot drive.

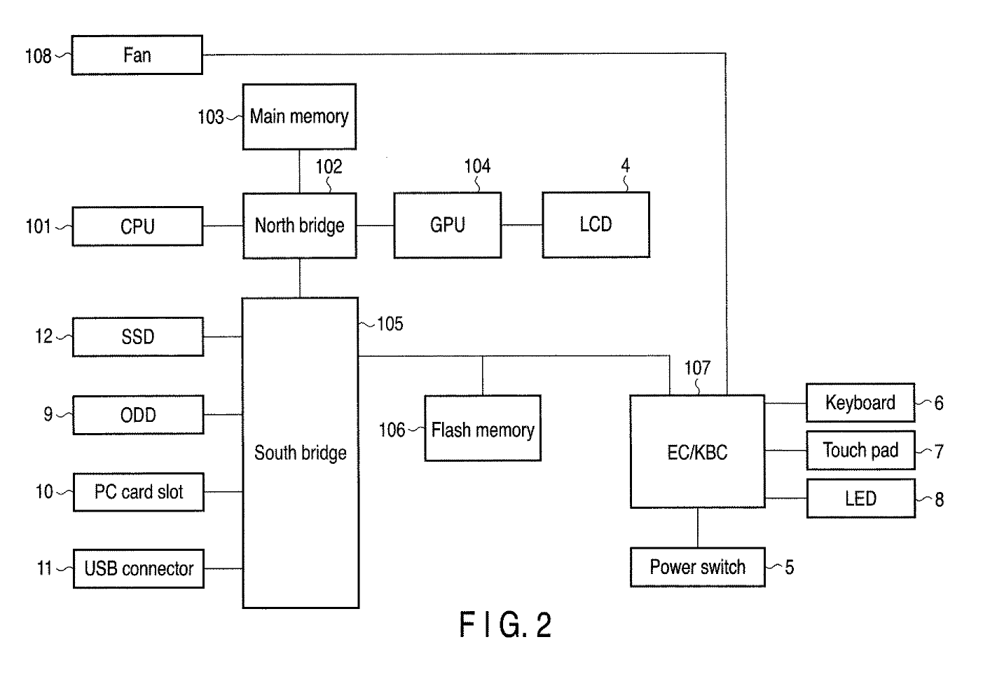

FIG. 2 is an exemplary diagram showing the system configuration of the computer 1.

As shown in FIG. 2, the computer 1 includes a CPU 101, north bridge 102, main memory 103, graphic processing unit (GPU) 104, south bridge 105, flash memory 106, embedded controller/keyboard controller (EC/KBC) 107 and fan 108 in addition to the LCD 4, power source switch 5, keyboard 6, touchpad 7, LED 8, ODD 9, PC card slot 10, USB connector 11 and SSD 12.

The CPU 101 is a processor that controls the operation of the computer 1 and executes an operating system and various application programs containing utilities loaded from the SSD 12 to the main memory 103. Further, the CPU 101 also executes a basic input/output system (BIOS) stored in the flash memory 106. The BIOS is a program For hardware control.

The north bridge 102 is a bridge device that connects the local bus of the CPU 101 to the south bridge 105. The north bridge 102 includes a function of making communication with the GPU 104 via the bus and contains a memory controller that controls access to the main memory 103. The CPU 104 controls the LCD 4 used as the display device of the computer 1.

The south bridge 105 is a controller that controls various devices such as PC cards loaded in the SSD 12, ODD 9 and PC card slot 10, a USE device connected to the USE connector 11 and the flash memory 106.

The EC/KBC 107 is an one-chip microcomputer in which a built-in controller for power management and a keyboard controller for controlling the keyboard 6 and touchpad 7 are integrated. The EC/KBC 107 also controls the LED 8 and the fan 108 for cooling.

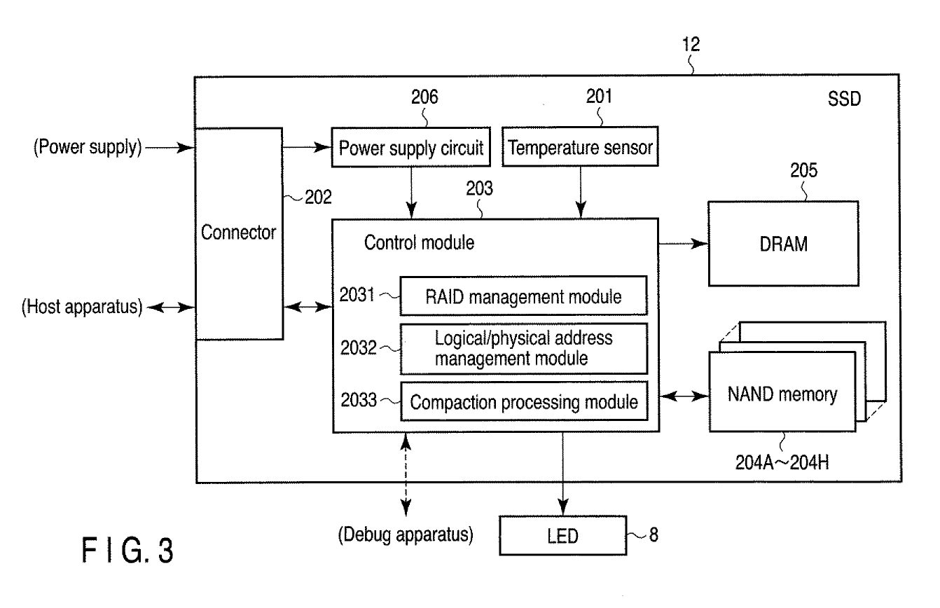

FIG. 3 is an exemplary block diagram showing the schematic configuration of the SSD 12 installed as an external storage device used as a boot drive of the computer 1 with the above system configuration.

As shown in FIG. 3, the SSD 12 is a nonvolatile external storage device that includes a temperature sensor 201, connector 202, control module 203, NAND memories 204A to 204H, DRAM 205 and power supply circuit 206 and in which data can be kept held even if the power supply is interrupted (data containing programs in the NAND memories 204A to 204H is not lost). Further, the SSD 12 is an external storage device of low power consumption that does not have a driving mechanism for a head and disk unlike the HDD and is highly shock-resistant.

The control module 203 that controls the data write and read operation with respect to the NAND memories 204A to 204H as a memory controller is connected to the connector 202, NAND memories 204A to 204H, DRAM 205 and power supply circuit 206. When the SSD 12 is mounted within the computer main body 2, the control module 203 is connected to the host apparatus, that is, the south bridge 105 of the computer main body 2 via the connector 202. Further, when the SSD 12 is provided in a singular form, the control module 203 can be connected to a debug device via a serial interface of, for example, the RS-232C standard as required.

As shown in FIG. 3, the control module 203 includes a RAID management module 2031, logical/physical address management module 2032 and compaction processing module 2033 that will be described later.

Each of the NAND memories 204A to 204H is a nonvolatile semiconductor memory including 16-Gbyte storage capacity, for example, and is a multi level cell (MLC)-NAND memory that can store two bits in each memory cell, for example. Generally, in the MLC-NAND memory, the number of rewrite operations is smaller in comparison with a single level cell (SLC)-NAND memory, but it is easy to increase the storage capacity,

The DRAM 205 is a memory device used as a cache memory in which data is temporarily stored when data is written or read with respect to the NAND memories 204A to 204H by means of the control module 203. The power supply circuit 206 creates and supplies electric power used for operating the control module 203 by using the power supplied from the EC/KBC 107 via the south bridge 105 and connector 202 as electric supply power.

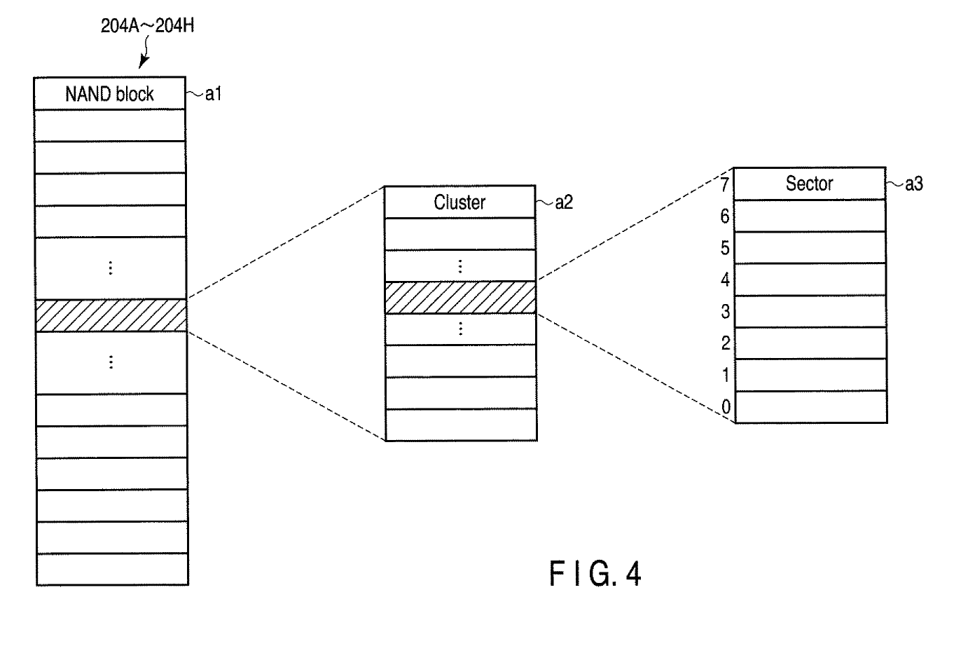

FIG. 4 is an exemplary conceptual diagram showing the schematic configuration of the NAND memories 204A to 204H incorporated in the SSD 12.

In a physical address space configured by the NAND memories 204A to 204H, a sector of 512 bytes is defined as a sector “a3” used as the physical usage minimum unit and a cluster of data size formed by collecting eight sectors “a3”, that is, 512 bytes×8 sectors=4,096 bytes is defined as a cluster “a2” used as the data management unit. In the SSD 12, the page size that is the physical data write unit or read unit in the NAND memories 204A to 204H is set to 4,314 bytes. That is, in the SSD 12, one cluster “a2” is stored in one page and a redundant area of 218 bytes is provided in each page (4,314 bytes−4,096 bytes 218 bytes). Setting of the page size is given as only one example and it is of course possible to set the page size so as to store two or more clusters “a2” in one page.

The NAND memories 204A to 204H are each formed by a plurality of NAND blocks “a1” that can be independently operated and each NAND block “a1” is formed by 128 pages. That is, 128 clusters “a2” are stored in each NAND block “a1”. In the SSD 12, each NAND group is formed by 16 NAND blocks and the management of the storage area is performed by simultaneously erasing data in the NAND group (16×128=2,048 clusters) unit, for example.

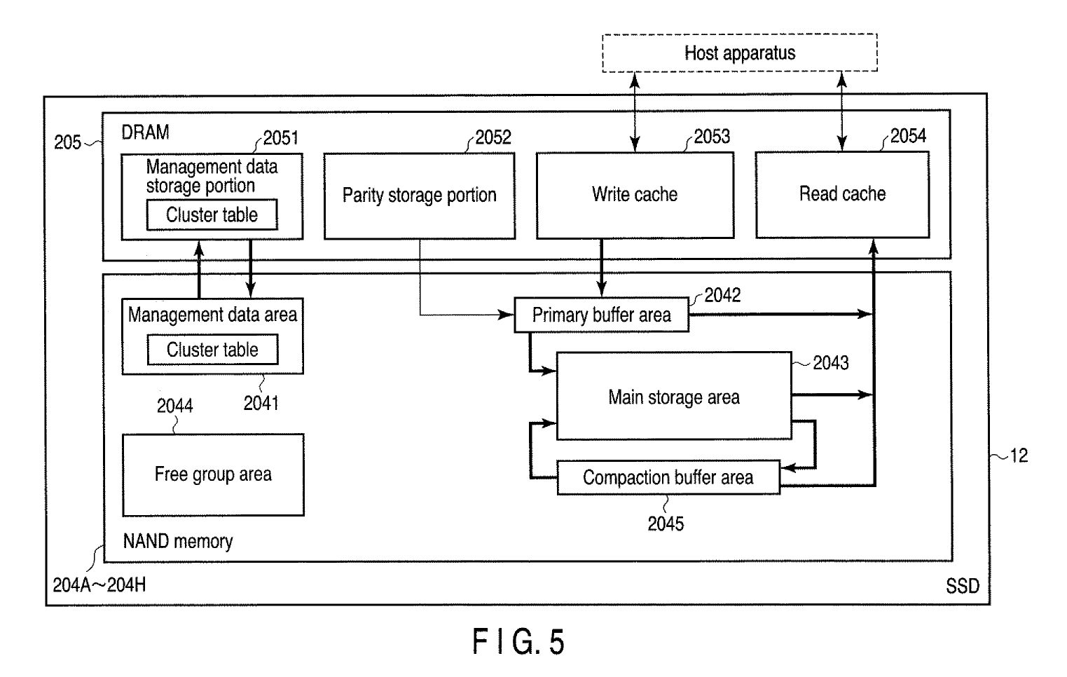

FIG. 5 is an exemplary conceptual diagram for illustrating the operation principle of the SSD 12.

As shown in FIG. 5, in the DRAM 205 used as a cache memory, a management data storage portion 2051, parity storage portion 2052, write cache 2053 and read cache 2054 are provided. Further, each storage area of the NAND memories 204A to 204H is dynamically allocated as one of a management data area 2041, primary buffer area 2042, main storage area 2043, free group area 2044 and compaction buffer area 2045.

The management data area 2041 is an area to store a cluster table indicating the correspondence relation between logical cluster addresses (logical block address [LBA]) and physical positions in the NAND memories 204A to 204H. The control module 203 fetches the cluster table and writes the same to the management data storage portion 2051 in the DRAM 205 when booting from the SSD 12 and accesses the NAND memories 204A to 204H by using the cluster table in the DRAM 205. For management of the cluster table, the control module 203 includes the logical/physical address management module 2032.

The cluster table in the DRAM 205 is written back to the NAND memories 204A to 204H when a predetermined command issued, for example, when shutting down of the SSD 12 is received. Further, in the management data storage portion 2051 and management data area 2041, pointer Information indicating write positions in the primary buffer area 2042 and compaction buffer area 2045 is stored.

When a data write request is issued from the host apparatus, the control module 203 writes the data at the write position of the primary buffer area 2042 and updates the cluster table in the DRAM 205 to set the write position in correspondence to a specified cluster address while temporarily storing the data in the write cache 2052 in the DRAM 205. If the NAND group allocated as the primary buffer area 2042 becomes full because of writing the data, the control module 203 manages matters by moving the NAND group to the main storage area 2043, and newly allocating one of the free NAND groups, which is remaining as the free group area 2044 and is set in an unused state, as the primary buffer area 2042.

The SSD 12 is a storage device of a type in which data is additionally written, data before updating is invalidated at the so-called data update time and data after updating is newly written to the internal primary buffer area 2042. That is, for example, data replacement will not occur in the NAND group of the main storage area 2043. At the data update time, the logical/physical address management module 2032 of the control module 203 performs a process of invalidating data before updating and a process of updating the cluster table caused by newly writing data after updating.

On the other hand, when a data read request is issued from the host apparatus and if the data is not present in the read cache 2054 in the DRAM 205, the control module 203 acquires the position of a specified cluster address in the NAND memories 204A to 204H by referring to the cluster table in the DRAM 205, reads data stored in the above position, writes the data to the read cache 2054 and returns the data to the host apparatus. If the requested data is present in the read cache 2054, the control module 203 instantly returns the data to the host apparatus without accessing the NAND memories 204A to 204H.

In the SSD 12, the control module 203 includes the RAID management module 2031 as a mechanism for enhancing data redundancy so that data in a page will not be lost even if a read error occurs in any one of the pages.

As described before, in the SSD 12, 16 NAND blocks each of which is formed by 128 pages and that can be independently operated are combined as one set to form a NAND group. In order to enhance data write efficiency with respect to the thus formed NAND group, when data of plural pages is written, write data of one page is transferred to one NAND block and then write data of a next one page is transferred to another NAND block without waiting for completion of the write operation of the former data. That is, 16 NAND blocks forming the same NAND group are logically connected in parallel.

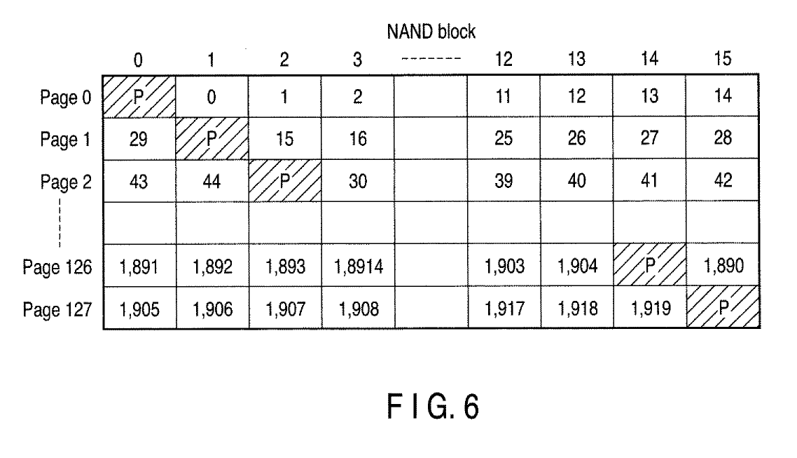

Therefore, as shown in FIG. 6, first, the RAID management module 2031 creates parity data of one page for every pages of the number (n) of NAND blocks forming the same group. More specifically, a process of creating parity data that can restore one data among n-1 data items based on other n-2 data Items each time n-1 data items are written and writing the thus created parity data to an n^{th} page (“P” in FIG. 6) is performed. The created parity data is transferred to the primary buffer area 2042 via the parity storage portion 2052 of the DRAM 205 and is thus written therein.

As a result, even if a read error occurs in any one of the pages, data of the page can be restored, and therefore, data redundancy can be enhanced. When a read error occurs in a certain page and data of the page is restored by using the other data and the parity data, the RAID management module 2031 performs a data update process of writing the data to another page at this time point in the internal portion.

In FIG. 6, an example wherein a page to which the parity data is written is slid one by one to change the NAND block is shown, but this invention is not limited to this example. For example, a certain NAND block can be fixedly used. Note, as described before, since the SSD 12 is a storage device of a type in which data is additionally written, the data update process is performed by invalidating data before updating and newly writing data after updating. However, invalidated data is treated as data necessary to restore other data in the internal portion.

In the SSD 12 that performs the data write and read operations according to the flow explained with reference to FIG. 5, it is preferable that the number of free NAND groups, which remaining as the free group area 2044 and is set in the unused state, be always kept greater than or equal to a predetermined standard number in order to maintain the data write efficiency. For this purpose, the control module 203 includes the compaction processing module 2033. When the number of free NAND groups becomes less than or equal to a predetermined number, the control module 203 performs compaction by means of the compaction processing module 2033.

First, the compaction processing module 2033 allocates one of the free NAND groups, which is remaining as the free group area 2044 and is set in the unused state, as the compaction buffer area 2045. Then, the compaction processing module 2033 selects one of the NAND groups of the main storage area 2043 which contains the least number of valid data items (valid clusters), that is, the largest number of invalidated data items (invalidated clusters) and rearranges only the valid clusters of the selected NAND group in the compaction buffer area 2045. The compaction processing module 2033 performs the process of updating the cluster table accompanied by the valid cluster rearranging process.

When all of the valid clusters in the selected NAND group have been completely rearranged, the NAND group is returned to the free group area 2044. Subsequently, the NAND group containing the second least number of valid clusters is selected, only the valid clusters are similarly rearranged in the compaction buffer area 2045 and then the NAND group is returned to the free group area 2044. The above process is repeatedly performed and if the NAND group allocated as the compaction buffer area 2045 becomes full, the compaction processing module 2033 shifts the NAND group to the main storage area 2043 and allocates a new free NAND group as the compaction buffer area 2045. For example, when a predetermined number of free NAND groups can be newly acquired, the compaction processing module 2033 terminates the compaction.

That is, the compaction processing module 2033 acquires n-1 free NAND groups at maximum by rearranging valid clusters scattered in n NAND groups (in an order starting from a group having the largest number of invalidated clusters) in n-1 or fewer NAND groups.

Since the compaction is to move valid clusters in a certain NAND group onto another NAND group, that is, rearrange data, it naturally becomes necessary to update the cluster table. Therefore, the logical/physical address management module 2032 includes a mechanism for efficiently and economically acquiring a logical address from a physical address and it is possible to rapidly update the address table at the data rearrangement time.

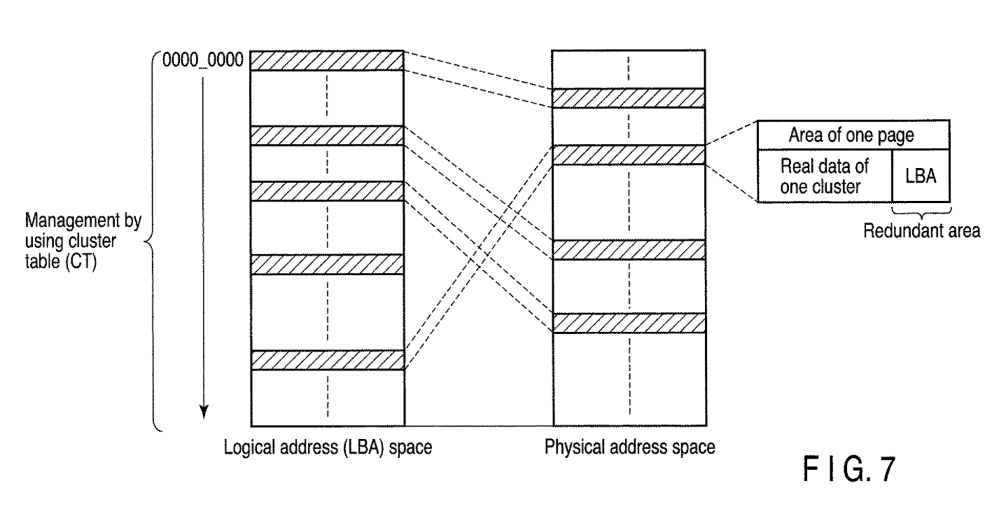

FIG. 7 is an exemplary conceptual diagram for illustrating a management of a correspondence relationship between a physical address space and a logical address space of the NAND memories 204A to 204H of the SSD 12 performed by the logical/physical address management module 2032.

As shown in FIG. 7, the physical address space and logical address space of the NAND memories 204A to 204H are dynamically allocated in the cluster unit. The cluster table is formed by providing one entry for each logical address, arranging the entries fin an order of logical addresses and storing physical addresses set in correspondence to the respective logical addresses so as to acquire a physical address by using the logical address as a search key. When writing, the logical/physical address management module 2032 performs a process of storing a physical address indicating the data write position in the entry of a specified logical address.

Further, in addition to the process for the cluster table, at the time of data write, the logical/physical address management module 2032 performs a process of storing a logical address (LBA in FIG. 7) set in correspondence to the physical address indicating the data write position in the entry of a specified logical address in a redundant area of a page to which the data has been written.

By storing corresponding logical addresses in the redundant area of each page, the logical/physical address management module 2032 can instantly acquire a logical address allocated to to-be-rearranged data from the redundant area of a page before rearrangement when compaction is performed by the compaction processing module 2033. Thus, it rapidly performs a process of updating a target entry of the cluster table into a physical address after rearrangement.

In FIG. 7, an example in which real data of one cluster is stored in each page is shown, but as described before, page size can be set to store two or more clusters in each page. Therefore, in this case, logical address information containing logical addresses of two or more stored real data items may be stored in the redundant area.

Thus, in the SSD 12, logical address information allocated to data stored in a page is stored in the redundant area of each page. Then, the RAID management module 2031 creates parity data that can be used to restore one logical address information among n-1 logical address information items based on other n-2 logical address information items in the logical address information stored in the redundant area. The thus created parity data is stored in the redundant area of an n^{th} page represented by “P” in FIG. 6.

As a result, when a read error occurs in any one of the pages, not only the data of the page but also the logical address information of the redundant area can be restored, and therefore, data redundancy can be further enhanced.

The RAID management module 2031 periodically performs a patrol process using two types of parity data items. More specifically, it reads data of 16 pages and checks whether each page can be read or not. If a page in which a read error occurs is present, it restores data of the page and logical address information at this time point (recreates each parity data in the case of a page for parity) and performs a recovery process of writing the data to another page. If all of the 16 pages can be read, it checks whether values of the two types of parity data are correct or not. If the value of the parity data is erroneous, it performs a predetermined error process. For example, it performs a data correction process if an error correction code (ECC) is provided or it informs the host apparatus of that a data error has occurred. By performing the patrol process, the reliability of the SSD 12 can be enhanced.

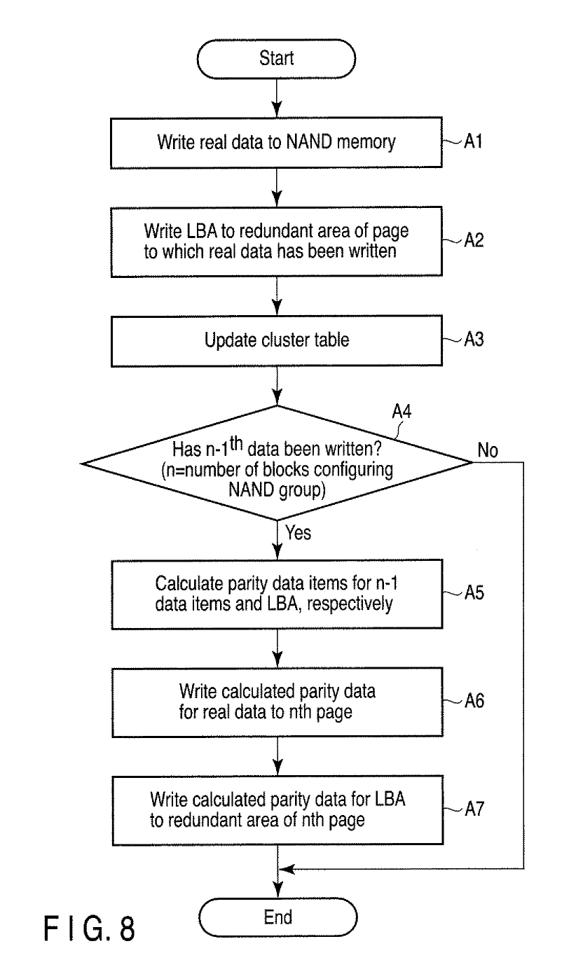

FIG. 8 is an exemplary flowchart for illustrating the operation procedure of a data write process performed by the control module 203 of the SSD 12.

When receiving a data write request, the control module 203 writes the data to the primary buffer area 2042 of the NAND memories 204A to 204H (block A1) and, at the same time, writes a specified logical address (cluster address) to a redundant area of a page to which the data has been written (block A2).

Further, the control module 203 updates a cluster table to store a physical address indicating the write position of the data in an entry of a specified cluster address (block A3).

Subsequently, the control module 203 determines whether or not the data write position corresponds to an n-1^{th} position (block A4, where n is the number of NAND blocks forming the NAND group), and if the position corresponds to the n-1^{th} position (YES in block A4), it creates parity data for n-1 data items and logical address information (block A5). Then, the control module 203 writes the parity data for the data to an n^{th} page (block A6) and writes the parity data for the logical address information to the redundant area of the same page (block A7).

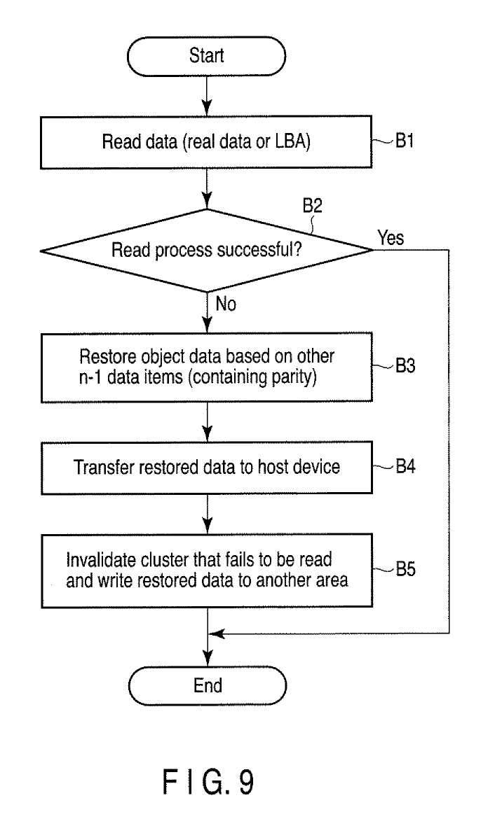

FIG. 9 is an exemplary flowchart for illustrating the operation procedure of a data read process performed by the control module 203 of the SSD 12.

When receiving a data read request, the control module 203 converts a specified logical address into a physical address according to the cluster table and reads data stored at a position in the NAND memories 204A to 204H indicated by the physical address (block B1).

If the read process fails (NO in block B2), the control module 203 restores the data that is requested to be read by use of other n-1 data items forming the same NAND group (block B3) and transfers the restored data to the host apparatus (block B4). At this time, the control module 203 performs a recovery process of invalidating data that fails to be read and writing the restored data to another page (block B5).

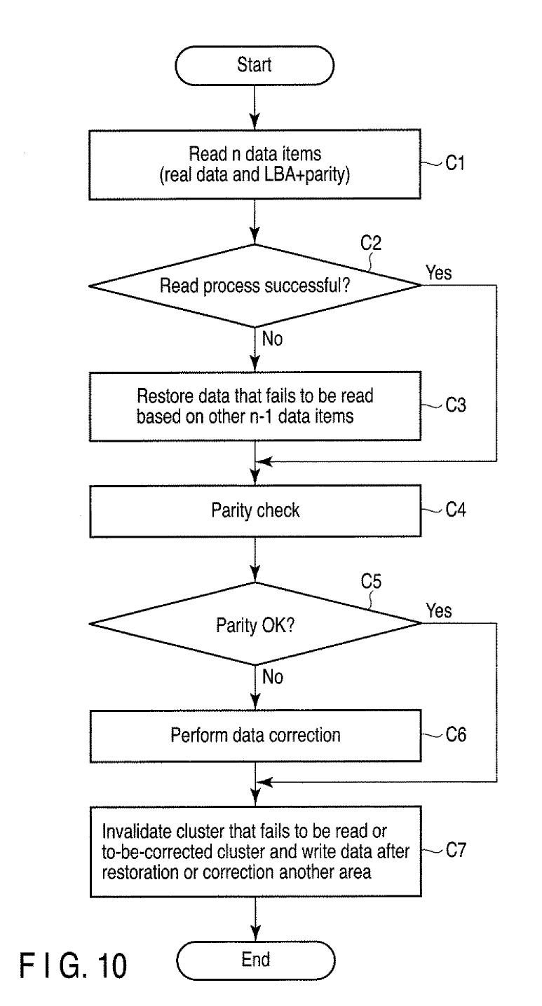

FIG. 10 is an exemplary flowchart for illustrating the operation procedure of a patrol process performed by the control module 203 of the SSD 12.

The control module 203 reads n (the number of NAND groups forming the NAND group) data items for each predetermined period (block C1) and if any one of data items fails to be read (NO in block C2), it restores the data that fails to be read by use of other n-1 data items (block C3).

Subsequently, the control module 203 checks parity data by use of n data items (block C4) and if an error is detected in the parity data (NO in block C5), it performs a data correction process (block C6). Then, the control module 203 rearranges data restored or corrected during the patrol process (block C7).

As described above, in the SSD 12, when data is written Lo the NAND memories 204A to 204H, parity data of one page is created for every n pages for the NAND group configured by the n NAND blocks to enhance data redundancy. Further, one parity data is created for every n logical address information items for the logical address information stored in the redundant area of each page to further enhance the data redundancy.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A nonvolatile semiconductor memory drive comprising:
a nonvolatile semiconductor memory; and
a controller configured to control a process of writing and reading data with respect to the nonvolatile semiconductor memory,
the controller comprising:
a data management module configured to create, each time n-1 data items of page size are written, first parity data used to restore one data item among the n-1 data items based on the other n-2 data items and to write the created first parity data to an n^{th} page for a plurality of groups, the page size being one of a data write unit to the nonvolatile semiconductor memory and a data read unit from the nonvolatile semiconductor memory, the plurality of groups being formed by connecting n memory blocks in parallel that are independently operable as a management unit of a storage area in the nonvolatile semiconductor memory; and
a logical address storage module configured to store logical address information containing logical addresses indicating storage positions in a logical address space of the nonvolatile semiconductor memory in a redundant area of a page, the logical addresses being allocated to data items of cluster size defined as a management unit of data in the nonvolatile semiconductor memory stored in the page,
wherein the data management module comprises a write module that creates second parity data used to restore one logical address information item among n-1 logical address information items stored in redundant areas of n-1 pages based on the other n-2 logical address information items and writes the created second parity data to the redundant area of the n^{th} page when the first parity data is written to the n^{th} page.

2. The nonvolatile semiconductor memory drive of claim 1, wherein the data management module of the controller comprises a module that restores one of a data item and a logical address information item by using one of the other n-2 data items and logical address information items and one of the first and second parity data items and rearranges the restored one of the data item and the logical address information item in another page, when one of the data item and logical address information item fails to be read.

3. The nonvolatile semiconductor memory drive of claim 1, wherein the controller further comprises an address table management module configured to update an address table including the correspondence of logical addresses indicating positions in a logical address space of the nonvolatile semiconductor memory and physical addresses indicating positions in a physical address space by using a logical address contained in logical address information stored in the redundant area of a page in which to-be-rearranged data is stored and allocated to the data, when the data is rearranged in the nonvolatile semiconductor memory.

4. The nonvolatile semiconductor memory drive of claim 1, wherein the data management module of the controller reads the n-1 data items, logical address information and first and second parity data items for each predetermined period, checks whether the n-1 data items and logical address information are readable and checks whether values of the first and second parity data items are correct.

5. A data management method of a nonvolatile semiconductor memory drive comprising a nonvolatile semiconductor memory and a controller configured to control a process of writing and reading data with respect to the nonvolatile semiconductor memory, the method comprising:
creating, each time the n-1 data items of page size are written, first parity data used to restore one data among n-1 data items based on the other n-2 data items and writing the created parity data to an n^{th} page for a plurality of groups, the page size being one of a data write unit to the nonvolatile semiconductor memory and a data read unit from the nonvolatile semiconductor memory, the plurality of groups being formed by connecting n memory blocks in parallel that are independently operable as a management unit of a storage area in the nonvolatile semiconductor memory;
storing logical address information containing logical addresses indicating storage positions in a logical address space of the nonvolatile semiconductor memory in a redundant area of the page, the logical addresses being allocated to data items of cluster size defined as a management unit of data in the nonvolatile semiconductor memory stored in the page; and
creating second parity data used to restore one logical address information item among n-1 logical address information items stored in redundant areas of n-1 pages based on the other n-2 logical address information items and writing the created second parity data to the redundant area of the n^{th} page when the first parity data is written to the n^{th} page.

6. The data management method of claim 5, further comprising restoring one of a data item and a logical address information item by using one of the other n-2 data items and logical address information items and one of the first and second parity data items and rearranging the restored one of data and logical address information in another page, when one of the data and logical address information fails to be read.

7. The data management method of claim 5, further comprising reading the n-1 data items, logical address information and the first and second parity data items for each predetermined period, checking whether the n-1 data items and logical address information are readable and checking whether values of the first and second parity data items are correct.
